(19) United States
(12) Patent Application Publication
(10) Pub. No.: US 2026/0136468 A1
(43) Pub. Date: May 14, 2026

(54) DISPLAY DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventors: Jianbin XIE, Wuhan, Hubei (CN); Kuihua YOU, Wuhan, Hubei (CN); Cui ZHANG, Wuhan, Hubei (CN)

(21) Appl. No.: 18/995,487

(22) PCT Filed: Nov. 20, 2024
(86) PCT No.: PCT/CN2024/133088

§ 371 Date: Jan. 16, 2025

(30) Foreign Application Priority Data
Nov. 11, 2024 (CN) 202411608148.3

(51) Int. Cl. H05K 1/18

(52) U.S. Cl. CPC H05K 1/189; H05K 2201/09409; H05K 2201/10128

(57) ABSTRACT

A display device is provided. The display device includes a display panel, a flexible circuit board and a printed circuit board that are connected. A first display terminal and a second display terminal disposed in series in the display panel are respectively bonded and connected to a first flexible terminal and a second flexible terminal in the flexible circuit board. The flexible circuit board further includes a first measurement terminal and a second measurement terminal. The first measurement terminal is connected to the first flexible terminal, and the second measurement terminal is connected to the second flexible terminal.

### TECHNICAL FIELD

The present disclosure relates to the field of display, and in particular, to a display device.

### BACKGROUND

In the existing display devices, one end of the flexible circuit board is generally bonded and connected to a bonding area of the display panel, and the other end of the flexible circuit board is generally bonded and connected to the printed circuit board.

In order to evaluate the stability of the bonding process of the product, it is generally necessary to test the bonding impedance between the source driving chip and the display panel (chip on panel, COP), the bonding impedance between the flexible circuit board and the display panel (flexible printed circuit (FPC) on panel, FOP), and the bonding impedance between the circuit board and the flexible circuit board (FPC on board, FOB). The testing point positions of the above three kinds of bonding impedance are currently disposed in the printed circuit board, which increases the size of the printed circuit board and compresses the arrangement space of the internal components in the display device, and which is contrary to the current demands for ultra-narrow printed circuit board.

### SUMMARY

The present disclosure provides a display device to address the technical problem of the large size of the printed circuit board in the existing display device.

In order to solve the above technical problem, the technical solutions provided by the present disclosure are as follows.

The present disclosure provides a display device including:
a display panel including a display portion and a display bonding portion disposed on one side of the display portion, the display bonding portion includes a first display terminal and a second display terminal disposed in series;
a flexible circuit board including a first bonding portion and a second bonding portion, the first bonding portion is bonded and connected to the display bonding portion, the first bonding portion includes a first flexible terminal and a second flexible terminal, the first flexible terminal is bonded and connected to the first display terminal, and the second flexible terminal is bonded and connected to the second display terminal; and
a printed circuit board disposed on a side of the flexible circuit board away from the display panel, the printed circuit board includes a printed bonding portion bonded and connected to the second bonding portion;
the flexible circuit board further includes a first measurement terminal and a second measurement terminal disposed on a side of the flexible circuit board away from the first bonding portion, the first measurement terminal is connected to the first flexible terminal, and the second measurement terminal is connected to the second flexible terminal.

A display device including:
a display panel including a display portion and a display bonding portion disposed on one side of the display portion, the display bonding portion includes a first display terminal and a second display terminal disposed in series;
a flexible circuit board including a first bonding portion and a second bonding portion, the first bonding portion is bonded and connected to the display bonding portion, the first bonding portion includes a first flexible terminal and a second flexible terminal, the first flexible terminal is bonded and connected to the first display terminal, and the second flexible terminal is bonded and connected to the second display terminal;
a printed circuit board, the printed circuit board is disposed on a backlight side of the display panel, a part of the flexible circuit board is bent to the backlight side of the display panel, and the printed circuit board includes a printed bonding portion bonded and connected to the second bonding portion; and
a support structure disposed between the display panel and the flexible circuit board;
the flexible circuit board further includes a first measurement terminal and a second measurement terminal disposed on a side of the flexible circuit board away from the first bonding portion, the first measurement terminal is connected to the first flexible terminal, and the second measurement terminal is connected to the second flexible terminal.

### BRIEF DESCRIPTION OF THE DRAWINGS

FIG. 1 is a diagram of a structure of a display device according to some embodiments of the present disclosure;

FIG. 2 is a diagram of a first cross-sectional structure of a display device according to some embodiments of the present disclosure;

FIG. 3 is a diagram of a second cross-sectional structure of a display device according to some embodiments of the present disclosure;

FIG. 4 is a schematic diagram of a first position of measurement terminals in a display device according to some embodiments of the present disclosure;

FIG. 5 is a schematic diagram of terminals in a display panel, a flexible circuit board and a printed circuit board in a display device according to some embodiments of the present disclosure;

FIG. 6 is a schematic diagram of a second position of measurement terminals in a display device according to some embodiments of the present disclosure.

### DETAILED DESCRIPTION

The technical solutions in the embodiments of the present disclosure will be clearly and completely described below with reference to the accompanying drawings in the embodiments of the present disclosure. It is apparent that the embodiments described are only part of the embodiments of the present disclosure, but not all the embodiments of the present disclosure. Based on the embodiments in the present disclosure, all other embodiments obtained by those skilled in the art without making creative efforts fall within the scope of protection of the present disclosure. In addition, it should be understood that the specific embodiments described herein are only used to illustrate and explain the present disclosure, and are not intended to limit the present disclosure.

In the description of the present disclosure, it should be understood that the orientation or positional relationship indicated by terms such as “length”, “width”, “thickness”, “upper”, “lower”, “front”, “back”, “left”, “right”, “top”, “bottom”, “inner”, “outer”, and the like are based on the orientation or positional relationship shown in the accompanying drawings. It is only for the convenience of description of the present disclosure and simplifying the description, and it does not indicate or imply that the device or element referred to must have a specific orientation, be constructed and operated in a specific orientation, therefore, it should not be interpreted as limitations of the present disclosure.

In addition, the terms “first” and “second” are only used for descriptive purposes, and cannot be understood as indicating or implying relative importance or implying the quantity of technical features indicated. Thus, the features defined as the “first” and “second” may explicitly or implicitly include one or more of the described features. In the description of the present disclosure, “a plurality of” means two or more than two, at least one refers to one, two or more than two, unless otherwise expressly and specifically limited.

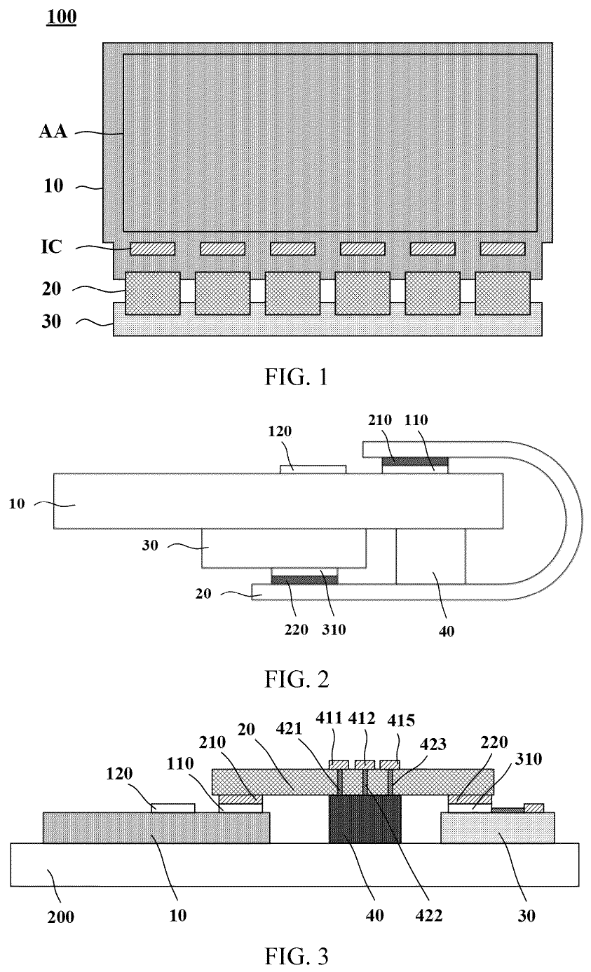

Referring to FIG. 1 to FIG. 6, the present disclosure proposes a display device 100, the display device 100 includes a display panel 10, a flexible circuit board 20 and a printed circuit board 30 that are connected. For display devices 100 of different sizes, different numbers of flexible circuit boards 20 can be disposed in the present disclosure.

In some embodiments, the display panel 10 includes a display portion AA and a display bonding portion 110 disposed on one side of the display bonding portion AA. The display bonding portion 110 includes a first display terminal 112a and a second display terminal 112b disposed in series. The flexible circuit board 20 includes a first bonding portion 210 and a second bonding portion 220. The first bonding portion 210 is bonded and connected to the display bonding portion 110. The first bonding portion 210 includes a first flexible terminal 212a and a second flexible terminal 212b, the first flexible terminal 212a is bonded and connected to the first display terminal 112a, and the second flexible terminal 212b is bonded and connected to the second display terminal 112b. The printed circuit board 30 is disposed on the side of the flexible circuit board 20 away from the display panel 10, and the printed circuit board 30 includes a printed bonding portion 310 bonded and connected to the second bonding portion 220.

In some embodiments, the flexible circuit board 20 further includes a first measurement terminal 411 and a second measurement terminal 412 disposed on the side of the flexible circuit board 20 away from the first bonding portion 210. The first measurement terminal 411 is connected to the first flexible terminal 212a, and the second measurement terminal 412 is connected to the second flexible terminal 212b.

In some embodiments, the printed circuit board 30 is disposed on the backlight side of the display panel 10, and part of the flexible circuit board 20 is bent to the backlight side of the display panel 10. That is, one end of the flexible circuit board 20 can be bonded and connected to the display bonding portion 110, and the other end of the flexible circuit board 20 is bent to the back side of the display panel 10 and is bonded and connected to the printed bonding portion 310. In this way, the arrangement of the flexible circuit board 20 and the printed circuit board 30 can reduce the frame width of the display device 100 to achieve a narrow frame design of the product.

In the present disclosure, the first measurement terminal 411 and the second measurement terminal 412 are disposed on the surface of the flexible circuit board 20 away from the bonding side, so that the first measurement terminal 411, the second measurement terminal 412, the first flexible terminal 212a, the second flexible terminal 212b, the first display terminal 112a and the second display terminal 112b can form a series circuit, so that the measurement point of the bonding impedance between the display panel 10 and the flexible circuit board 20 can be moved from the printed circuit board 30 to the flexible circuit board 20, which releases the space of the printed circuit board 30, reduces the size of the printed circuit board 30, and realizes the ultra-narrow frame design of the printed circuit board 30. Therefore, more space inside the display device 100 are available to arrange other components, for example, increasing the volume of the battery in the display device 100 to improve the endurance of the product.

It should be noted that, in order to facilitate the description of the technical solution of the present disclosure, the display panel 10, the printed circuit board 30 and the flexible circuit board 20 in the present disclosure can be all disposed on the same bearing platform 200 to facilitate the test of the bonding impedance, for example, the structure shown in FIG. 3.

It should be noted that the display panel 10 can be a liquid crystal display (LCD) panel, an organic light-emitting diode (OLED) panel, or a Mini light-emitting diode (Mini LED) direct display panel, a Micro LED direct display panel, and the like.

The technical solutions of the present disclosure will now be described with reference to specific embodiments.

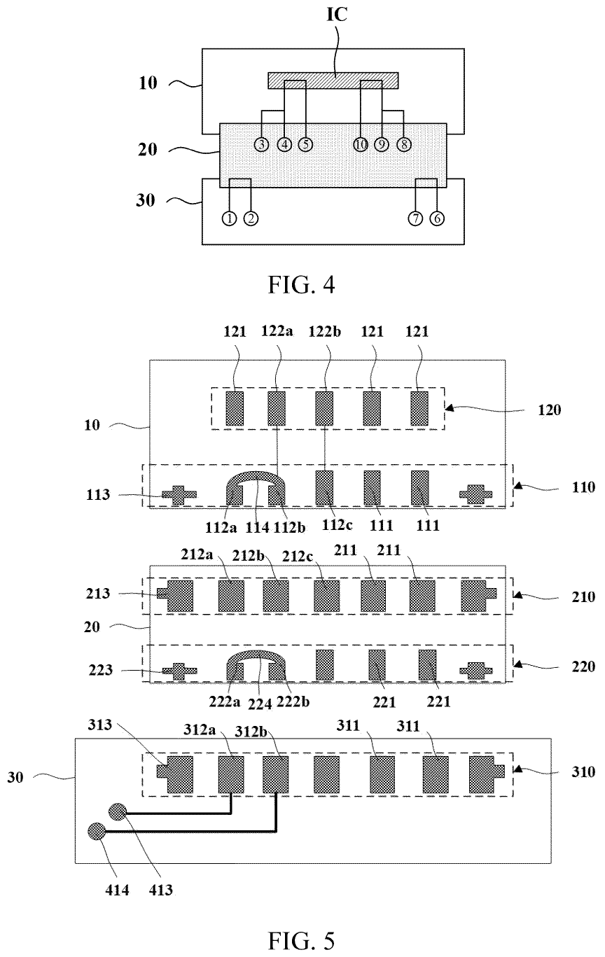

Referring to FIG. 4 and FIG. 5, the display bonding portion 110 may include a plurality of display bonding terminals 111 and the first alignment marks 113 disposed at two sides of the plurality of display bonding terminals 111. The plurality of display bonding terminals 111 include the first display terminal 112a and the second display terminal 112b that are used for impedance testing. The first display terminal 112a and the second display terminal 112b are disposed adjacent to each other or at least one display bonding terminal 111 is disposed between the first display terminal 112a and the second display terminal 112b.

Referring again to FIG. 4 and FIG. 5, since the first display terminal 112a and the second display terminal 112b are configured to measure the bonding impedance between the display panel 10 and the flexible circuit board 20, in order to form a series circuit, in the present disclosure, a first connecting portion 114 can be disposed between the first display terminal 112a and the second display terminal 112b. One end of the first connecting portion 114 is electrically connected to the first display terminal 112a, and the other end of the first connecting portion 114 is electrically connected to the second display terminal 112b.

In some embodiments, the first connecting portion 114 may be in a U-shaped structure, and two ends of the U-shaped structure are respectively connected to the first display terminal 112a and the second display terminal 112b.

In some embodiments, the first display terminal 112a, the second display terminal 112b and the first connecting portion 114 can be formed in the same mask process as other display bonding terminals 111 in the display bonding portion 110.

Referring to FIG. 5, the first bonding portion 210 includes a plurality of first bonding terminals 211 and the second alignment marks 213 disposed at two sides of the plurality of first bonding terminals 211, and the first alignment mark 113 and the second alignment mark 213 are bonded in an aligned manner. One first bonding terminal 211 is bonded and connected to one first display terminal 112a, the plurality of first bonding terminals 211 include the first flexible terminal 212a and the second flexible terminal 212b that are used for impedance testing. The first flexible terminal 212a is corresponded and bonded to the first display terminal 112a, and the second flexible terminal 212b is corresponded and bonded to the second display terminal 112b.

That is, in the present disclosure, the first connecting portion 114 connecting the first display terminal 112a and the second display terminal 112b in series is disposed in the display bonding portion 110, so that the first display terminal 112a and the second display terminal 112b are directly connected in series, so that the first measurement terminal 411, the second measurement terminal 412, the first flexible terminal 212a, the second flexible terminal 212b, the first display terminal 112a, and the second display terminal 112b form a serious circuit. For example, in FIG. 4, the testing point 3 and the testing point 4 form a loop, and the testing point 8 and the testing point 9 form a loop. Therefore, the measurement point of the bonding impedance between the display panel 10 and the flexible circuit board 20 can be moved from the printed circuit board 30 to the flexible circuit board 20, thereby releasing the space of the printed circuit board 30.

Referring to FIG. 2, the flexible circuit board 20 includes a base layer, the first bonding portion 210 and the second bonding portion 220 are disposed on the first side of the base layer, and the first measurement terminal 411 and the second measurement terminal 412 are disposed on the second side of the base layer opposite to the first side.

In some embodiments, since the first flexible terminal 212a and the second flexible terminal 212b are located on the bonding side of the flexible circuit board 20, if the first measurement terminal 411 and the second measurement terminal 412 are both disposed on the same side as the terminals on the bonding side, then the first measurement terminal 411 and the second measurement terminal 412 are not accessible for the impedance testing fixture.

In some embodiments, the flexible circuit board 20 further includes a first testing lead 421 and a second testing lead 422. The first testing lead 421 and the second testing lead 422 penetrate the base layer, two ends of the first testing lead 421 are respectively connected to the first flexible terminal 212a and the first measurement terminal 411, and two ends of the second testing lead 422 are respectively connected to the second flexible terminal 212b and the second measurement terminal 412.

That is, in the present disclosure, the first measurement terminal 411, the first flexible terminal 212a, the first display terminal 112a and the first testing lead 421 are the first testing section of the FOP; and the second measurement terminal 412, the second flexible terminal 212b, the second display terminal 112b and second testing lead 422 are the second testing section of the FOP. The first testing section of the FOP and the second testing section of the FOP are connected in series through the first connecting portion 114, so that the first testing section of the FOP and the second testing section of the FOP form a series circuit to test the bonding impedance between the display panel 10 and the flexible circuit board 20.

In some embodiments, since the measurement terminal is configured to connect to the impedance testing fixture, the measurement terminal can have a relative smaller area. In the present disclosure, the area of the first measurement terminal 411 can be smaller than the area of the first flexible terminal 212a, and the area of the second measurement terminal 412 can be smaller than the area of the second flexible terminal 212b.

Referring to FIG. 3, the second bonding portion 220 includes a plurality of second bonding terminals 221 and the third alignment marks 223 disposed at two sides of the plurality of second bonding terminals 221. The printed circuit board 30 includes a plurality of printed bonding terminals 311 and the fourth alignment marks 313 disposed at two sides of the plurality of printed bonding terminals 311. The third alignment mark 223 and the fourth alignment mark 313 are bonded in an aligned manner, and one second bonding terminal 221 is bonded and connected to one printed bonding terminal 311.

In some embodiments, the plurality of second bonding terminals 221 may include the third flexible terminal 222a and the fourth flexible terminal 222b, and the plurality of printed bonding terminals 311 may include the first printed terminal 312a and the second printed terminal 312b. The third flexible terminal 222a is bonded and connected to the first printed terminal 312a, and the fourth flexible terminal 222b is bonded and connected to the second printed terminal 312b.

In some embodiments, for the bonding impedance test between the flexible circuit board 20 and the printed circuit board 30, in the present disclosure, a second connecting portion 224 can be disposed on the flexible circuit board 20, and two ends of the second connecting portion 224 can be respectively connected to third flexible terminal 222a and the fourth flexible terminal 222b, so that the first printed terminal 312a, the second printed terminal 312b, the third flexible terminal 222a and the fourth flexible terminal 222b can form a series circuit.

In this case, the printed bonding portion 310 further includes a third measurement terminal 413 and a fourth measurement terminal 414. The third measurement terminal 413 is electrically connected to the first printed terminal 312a, the fourth measurement terminal 414 is electrically connected to the second printed terminal 312b, and each of the third measurement terminal 413 and the fourth measurement terminal 414 is located on the same side of the printed circuit board 30 as the printed bonding portion 310.

In some embodiments, since the bonding side of the printed circuit board 30 is corresponded to the impedance testing fixture, the measurement terminals on the printed circuit board 30 can be disposed on the same side as the printed bonding terminals 311. Testing leads for bonding impedance testing can further be connected and disposed on the printed circuit board 30.

In some embodiments, the area of each of the first measurement terminal 411, the second measurement terminal 412, the third measurement terminal 413 and the fourth measurement terminal 414 is equal.

In some embodiments, due to the limitation of terminal arrangement space, the areas of terminals in different structures are different. In this case, due to the existence of alignment bonding error, in the present disclosure, the area of the first bonding terminal 211 can be larger than the area of the display bonding terminal 111, and the area of the printed bonding terminal 311 may be larger than the area of the second bonding terminal 221.

That is, the first printed terminal 312a, the third flexible terminal 222a and the third measurement terminal 413 are the first testing section of the FOB; and the second printed terminal 312b, the fourth flexible terminal 222b and the fourth measurement terminal 414 are the second testing section of the FOB. The first testing section of the FOB and the second testing section of FOB are connected in series through the second connecting portion 224, so that the first testing section of FOB and the second testing section of FOB form a series circuit to measure the bonding impedance between the printed circuit board 30 and the flexible circuit board 20. For example, in FIG. 4, the testing point 1 and the testing point 2 form a loop, and the testing point 6 and testing point 7 form a loop.

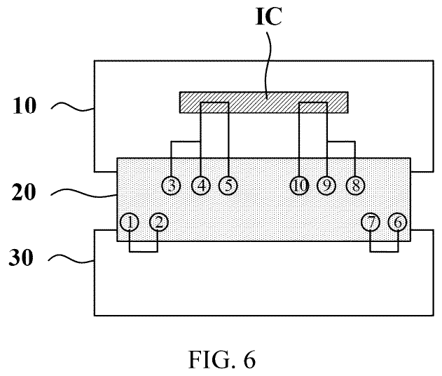

Referring to FIG. 6, the third measurement terminal 413 and the fourth measurement terminal 414 can be disposed on the flexible circuit board 20, and the second connecting portion 224 can be disposed on the printed circuit board 30, so that the measurement point of bonding impedance between the printed circuit board 30 and the flexible circuit board 20 an be moved from the printed circuit board 30 to the flexible circuit board 20, thereby further releasing the space of the printed circuit board 30. For example, in FIG. 6, the testing point 1 and the testing point 2 form a loop, and the testing point 6 and testing point 7 form a loop.

Referring to FIG. 4, the display panel 10 further includes a driving bonding portion 120 bonded and connected to the driving chip integrated circuit (IC). The driving bonding portion 120 includes a plurality of driving bonding terminals 121, and the plurality of driving bonding terminals 121 include a first driving terminal 122a and a second driving terminal 122b. The first driving terminal 122a and the second driving terminal 122b are respectively bonded and connected to two terminals connected in series in the driving chip IC, that is, the driving bonding terminal 121 can be multiplexed as a terminal for impedance testing.

In some embodiments, since there is not sufficient space to dispose measurement terminals in the driving chip IC and in the display panel 10, in the present disclosure, the testing points for the bonding impedance of the driving chip IC and the display panel 10 can be disposed on the flexible circuit board 20.

Referring to FIG. 5, the display bonding portion 110 further includes a third display terminal 112c disposed adjacent to the second display terminal 112b. The second display terminal 112b is electrically connected to the first driving terminal 122a, and the third display terminal 112c is electrically connected to the second driving terminal 122b.

In this case, the flexible circuit board 20 may further include a fifth flexible terminal 212c, a fifth measurement terminal 415 and a third testing lead 423. The fifth flexible terminal 212c is bonded and connected to the third display terminal 112c, the fifth measurement terminal 415 is disposed in the same layer as the first measurement terminal 411 and the second measurement terminal 412, and two ends of the third testing lead 423 are respectively connected to the fifth measurement terminal 415 and the fifth flexible terminal 212c.

Therefore, in the present disclosure, the second display terminal 112b, the first driving terminal 122a, the second flexible terminal 212b, and the second measurement terminal 412 that are electrically connected form the first testing section of COP and FOP; and the third display terminal 112c, the second driving terminal 122b, the fifth flexible terminal 212c, and the fifth measurement terminal 415 that are electrically connected form the second testing section of COP and FOP. The first testing section of COP and FOP and the second testing section of COP and FOP form a series circuit through two terminals connected in series in the driving chip IC, so as to measure the bonding impedance between the display panel 10 and the flexible circuit board 20 and the bonding impedance between the driving chip IC and the display panel 10. Since the first measurement terminal 411 and the second measurement terminal 412 can obtain the bonding impedance between the display panel 10 and the flexible circuit board 20, the bonding impedance between the driving chip IC and the display panel 10 in the present disclosure can be obtained based on the difference between the impedance measured between the fifth measurement terminal 415 and the second measurement terminal 412, and the impedance measured between the first measurement terminal 411 and the second measurement terminal 412. For example, in FIG. 4 and FIG. 6, the testing point 4 and testing point 6 form a loop, and the testing point 9 and testing point 10 form a loop.

In the present disclosure, three measurement terminals can be disposed on the flexible circuit board 20, and the three measurement terminals in the flexible circuit board 20 and three display bonding terminals 111 in the display panel 10 can be used to form the testing circuit of the bonding impedance of the COP and the FOP. In this case, the measurement terminals in the FOB can also be disposed on the flexible circuit board 20, so as to move the measurement terminals originally located on the printed circuit board 30 to the flexible circuit board 20, thereby releasing the space of the printed circuit board 30 and reducing the size of printed circuit board 30.

It should be noted that the terminals for measuring the impedance used in the present disclosure can only be used for impedance testing without signal transmission.

Referring to FIG. 2 and FIG. 3, the display device 100 further includes a support structure 40 disposed on the backlight side of the display panel 10. The support structure 40 is disposed between the display panel 10 and the flexible circuit board 20. When performing the impedance test, since it is required that the impedance testing fixture is in contact with the measurement terminals on the flexible circuit board 20, the arrangement of the support structure 40 increases the contact stability between the impedance testing fixture and the flexible circuit board 20, thereby improving the accuracy of the impedance test.

In some embodiments, the material of the support structure 40 may be foam.

In some embodiments, since the flexible circuit board 20 is required to be bent to the backside of the display panel 10, in order to improve the bonding stability of the flexible circuit board 20 and the printed circuit board 30, in the present disclosure, the thickness of the support structure 40 can be smaller than or equal to the thickness of the printed circuit board 30, that is, ensuring that the bonding surface of the flexible circuit board 20 and the bonding surface of the printed circuit board 30 are located on the same plane as much as possible.

It should be noted that the foam 40 in FIG. 2 and FIG. 3 is only a schematic diagram, and the size of the foam in the present disclosure shall be subject to the disclosure in the description.

It should be noted that the display device of the present disclosure can be any product or component with a display function such as a mobile phone, a tablet computer, a television, a display, a notebook computer, a digital photo frame, a navigator, and the like.

In the above embodiments, each embodiment is described with its own emphasis. For parts that are not described in detail in a certain embodiment, reference can be made to the relevant descriptions of other embodiments.

The technical solutions provided by the embodiments of the present disclosure are introduced in detail above. Specific examples are used herein to illustrate the principles and implementations of the present disclosure, and the above description of the embodiments is merely intended to help understand the technical solution and its core idea of the present disclosure. It should be understood that, a person skilled in the art may modify the technical solutions recorded in the foregoing embodiments, or to equivalently replace some of the technical features. However, these modifications or replacements do not cause the essence of the corresponding technical solution to depart from the scope of the technical solution of each embodiment of the present disclosure.

1. A display device comprising:
a display panel comprising a display portion and a display bonding portion disposed on one side of the display portion, wherein the display bonding portion comprises a first display terminal and a second display terminal disposed in series;
a flexible circuit board comprising a first bonding portion and a second bonding portion, wherein the first bonding portion is bonded and connected to the display bonding portion, the first bonding portion comprises a first flexible terminal and a second flexible terminal, the first flexible terminal is bonded and connected to the first display terminal, and the second flexible terminal is bonded and connected to the second display terminal; and
a printed circuit board disposed on a side of the flexible circuit board away from the display panel, wherein the printed circuit board comprises a printed bonding portion bonded and connected to the second bonding portion;
wherein the flexible circuit board further comprises a first measurement terminal and a second measurement terminal disposed on a side of the flexible circuit board away from the first bonding portion, the first measurement terminal is connected to the first flexible terminal, and the second measurement terminal is connected to the second flexible terminal.

2. The display device according to claim 1, wherein the display bonding portion further comprises a first connecting portion disposed between the first display terminal and the second display terminal, one end of the first connecting portion is electrically connected to the first display terminal, and another end of the first connecting portion is electrically connected to the second display terminal.

3. The display device according to claim 2, wherein the first connecting portion is in a U-shaped structure.

4. The display device according to claim 2, wherein the first display terminal, the second display terminal and the first connecting portion are formed in a same mask process as one or more other display bonding terminals for transmitting signals in the display bonding portion.

5. The display device according to claim 2, wherein the flexible circuit board comprises a base layer, a first testing lead and a second testing lead, the first bonding portion and the second bonding portion are disposed on a first side of the base layer, and the first measurement terminal and the second measurement terminal are disposed on a second side of the base layer opposite to the first side;
wherein the first testing lead and the second testing lead penetrate the base layer, two ends of the first testing lead are respectively connected to the first flexible terminal and the first measurement terminal, and two ends of the second testing lead are respectively connected to the second flexible terminal and the second measurement terminal.

6. The display device according to claim 5, wherein an area of the first measurement terminal is smaller than an area of the first flexible terminal, and an area of the second measurement terminal is smaller than an area of the second flexible terminal.

7. The display device according to claim 5, wherein the second bonding portion comprises a third flexible terminal, a fourth flexible terminal and a second connecting portion, and two ends of the second connecting portion are respectively connected to the third flexible terminal and the fourth flexible terminal;
wherein the printed bonding portion comprises a first printed terminal and a second printed terminal, the third flexible terminal is bonded and connected to the first printed terminal, and the fourth flexible terminal is bonded and connected to the second printed terminal.

8. The display device according to claim 7, wherein the printed bonding portion further comprises a third measurement terminal and a fourth measurement terminal, the third measurement terminal is electrically connected to the first printed terminal, the fourth measurement terminal is electrically connected to the second printed terminal, and the third measurement terminal and the fourth measurement terminal are located on a same side of the printed circuit board as the printed bonding portion.

9. The display device according to claim 8, wherein an area of each of the first measurement terminal, the second measurement terminal, the third measurement terminal and the fourth measurement terminal is equal.

10. The display device according to claim 8, wherein the display panel further comprises a driving bonding portion bonded and connected to a driving chip, the driving bonding portion comprises a first driving terminal and a second driving terminal, the first driving terminal and the second driving terminal are respectively bonded and connected to two terminals connected in series in the driving chip;
wherein the display bonding portion further comprises a third display terminal disposed adjacent to the second display terminal, the second display terminal is electrically connected to the first driving terminal, and the third display terminal is electrically connected to the second driving terminal.

11. The display device according to claim 10, wherein the flexible circuit board comprises:
a fifth flexible terminal bonded and connected to the third display terminal;
a fifth measurement terminal disposed on a same layer as the first measurement terminal and the second measurement terminal; and
a third testing lead, wherein two ends of the third testing lead are respectively connected to the fifth measurement terminal and the fifth flexible terminal.

12. The display device according to claim 1, wherein the display bonding portion comprises a plurality of display bonding terminals for transmitting signals, the printed bonding portion comprises a plurality of printed bonding terminals for transmitting signals, the first bonding portion comprises a plurality of first bonding terminals for transmitting signals, and the second bonding portion comprises a plurality of second bonding terminals for transmitting signals;
wherein an area of each of the first bonding terminals is larger than an area of each of the display bonding terminals, and an area of each of the printed bonding terminals is larger than an area of each of the second bonding terminals.

13. A display device comprising:
a display panel comprising a display portion and a display bonding portion disposed on one side of the display portion, wherein the display bonding portion comprises a first display terminal and a second display terminal disposed in series;
a flexible circuit board comprising a first bonding portion and a second bonding portion, wherein the first bonding portion is bonded and connected to the display bonding portion, the first bonding portion comprises a first flexible terminal and a second flexible terminal, the first flexible terminal is bonded and connected to the first display terminal, and the second flexible terminal is bonded and connected to the second display terminal;
a printed circuit board, wherein the printed circuit board is disposed on a backlight side of the display panel, a part of the flexible circuit board is bent to the backlight side of the display panel, and the printed circuit board comprises a printed bonding portion bonded and connected to the second bonding portion; and
a support structure disposed between the display panel and the flexible circuit board;
wherein the flexible circuit board further comprises a first measurement terminal and a second measurement terminal disposed on a side of the flexible circuit board away from the first bonding portion, the first measurement terminal is connected to the first flexible terminal, and the second measurement terminal is connected to the second flexible terminal.

14. The display device according to claim 13, wherein the display bonding portion further comprises a first connecting portion disposed between the first display terminal and the second display terminal, one end of the first connecting portion is electrically connected to the first display terminal, and another end of the first connecting portion is electrically connected to the second display terminal.

15. The display device according to claim 14, wherein the flexible circuit board comprises a base layer, a first testing lead and a second testing lead, the first bonding portion and the second bonding portion are disposed on a first side of the base layer, and the first measurement terminal and the second measurement terminal are disposed on a second side of the base layer opposite to the first side;
wherein the first testing lead and the second testing lead penetrate the base layer, two ends of the first testing lead are respectively connected to the first flexible terminal and the first measurement terminal, and two ends of the second testing lead are respectively connected to the second flexible terminal and the second measurement terminal.

16. The display device according to claim 15, wherein an area of the first measurement terminal is smaller than an area of the first flexible terminal, and an area of the second measurement terminal is smaller than an area of the second flexible terminal.

17. The display device according to claim 15, wherein the second bonding portion comprises a third flexible terminal, a fourth flexible terminal and a second connecting portion, and two ends of the second connecting portion are respectively connected to the third flexible terminal and the fourth flexible terminal;
wherein the printed bonding portion comprises a first printed terminal and a second printed terminal, the third flexible terminal is bonded and connected to the first printed terminal, and the fourth flexible terminal is bonded and connected to the second printed terminal.

18. The display device according to claim 17, wherein the printed bonding portion further comprises a third measurement terminal and a fourth measurement terminal, the third measurement terminal is electrically connected to the first printed terminal, the fourth measurement terminal is electrically connected to the second printed terminal, and the third measurement terminal and the fourth measurement terminal are located on a same side of the printed circuit board as the printed bonding portion.

19. The display device according to claim 13, wherein a thickness of the support structure is less than or equal to a thickness of the printed circuit board.

20. The display device according to claim 13, wherein a material of the support structure is foam.
